(19) United States
(12) Patent Application Publication
(10) Pub. No.: US 2015/0228511 A1
(43) Pub. Date: Aug. 13, 2015

(54) METHODS AND SYSTEMS FOR VIBRATORY CHEMICAL MECHANICAL PLANARIZATION

(71) Applicant: Globalfoundries, Inc., Grand Cayman (KY)

(72) Inventor: Michael Wedlake, Albany, NY (US)

(73) Assignee: Globalfoundries, Inc., Grand Cayman (KY)

(21) Appl. No.: 14/176,545

(22) Filed: Feb. 10, 2014

(51) Int. Cl. H01L 21/67; H01L 21/306

(52) U.S. Cl. CPC H01L 21/67075; H01L 21/30625

(57) ABSTRACT

Methods and a system for processing semiconductor substrates are provided. A method of processing a semiconductor substrate includes selecting a predetermined vibration profile that will achieve predetermined material removal characteristics from the semiconductor substrate in a chemical mechanical planarization (CMP) polish, actuating a vibration actuator based on the predetermined vibration profile, and polishing the semiconductor substrate based substantially entirely on the predetermined vibration profile achieved by actuation of the vibration actuator.

### TECHNICAL FIELD

Embodiments of the present disclosure are generally directed to methods and systems for vibratory chemical mechanical planarization during semiconductor manufacturing. More particularly, embodiments of the present disclosure are directed to methods and systems for chemical mechanical planarization with vibrating platens or wafers.

### BACKGROUND

In the global market, manufacturers of mass products must offer high quality devices at a low price. It is thus important to improve yield and process efficiency to minimize production costs. This holds especially true in the field of semiconductor fabrication, where it is essential to combine cutting-edge technology with volume production techniques. It is the goal of semiconductor manufacturers to reduce the consumption of raw materials and consumables while at the same time improving process tool utilization.

Chemical Mechanical Planarization (CMP) is a critical unit process for manufacturing of microelectronic and nanoelectronic devices. CMP typically utilizes mechanical abrasion and chemical reactions to remove portions of a semiconductor substrate. For example, CMP is traditionally accomplished by a polishing pad interacting with the semiconductor substrate in the presence of a polishing fluid. The polishing pad typically has a diameter about three times larger than the diameter of the semiconductor substrate. The polishing fluid is generally composed of abrasives and other molecular components.

During the CMP process, the polishing pad typically spins rotationally or in an orbital fashion. These rotations create velocity gradients, where the linear velocity of the polishing pad varies across the surface of the semiconductor substrate. The polishing head on which the semiconductor substrate is mounted is also typically rotated, creating an additional velocity gradient.

As semiconductor substrates continue to increase in size, several aspects of the traditional CMP process become less desirable. For example, energy efficiency decreases, tool footprint increases, creating sufficient shear is more difficult, and platen velocity gradients increase and result in decreased uniformity.

As such, it is desirable to provide improved methods and systems for CMP during semiconductor device fabrication. Furthermore, other desirable features and characteristics of the inventive subject matter will become apparent from the subsequent detailed description of the inventive subject matter and the appended claims, taken in conjunction with the accompanying drawings and this background of the inventive subject matter.

### BRIEF SUMMARY

Methods and systems for processing a semiconductor substrate are disclosed herein. In an exemplary embodiment, a method of processing a semiconductor substrate includes selecting a predetermined vibration profile that will achieve predetermined material removal characteristics from the semiconductor substrate in a chemical mechanical planarization (CMP) polish, actuating a vibration actuator based on the predetermined vibration profile, and polishing the semiconductor substrate based substantially entirely on the predetermined vibration profile achieved by actuation of the vibration actuator.

In accordance with another exemplary embodiment, a method of fabricating a semiconductor device includes selecting a predetermined vibration profile that will achieve predetermined material removal characteristics from the semiconductor substrate in a chemical mechanical planarization (CMP) polish, actuating a vibration actuator based on the predetermined vibration profile, and polishing the semiconductor substrate based substantially entirely on the predetermined vibration profile achieved by actuation of the vibration actuator and on maintaining a non-rotating platen and a non-rotating polishing head.

In accordance with another exemplary embodiment, a chemical mechanical planarization (CMP) system includes a platen, a polishing head, and a vibration assembly. The polishing head opposes the platen and the vibration assembly is coupled with the platen, the polishing head, or a combination thereof. The vibration assembly includes a controller capable of selecting a predetermined vibration profile that will achieve predetermined material removal characteristics from the semiconductor substrate in a chemical mechanical planarization (CMP) polish, actuating a vibration actuator based on the predetermined vibration profile, and polishing the semiconductor substrate based substantially entirely on the predetermined vibration profile achieved by actuation of the vibration actuator and on maintaining a non-rotating platen and a non-rotating polishing head.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

Exemplary embodiments of the present disclosure will hereinafter be described in conjunction with the following drawing figures, wherein like numerals denote like elements, and wherein:

FIG. 1 is a simplified diagram of a chemical mechanical planarization system in accordance with various embodiments;

FIG. 2 is a simplified diagram of a vibration assembly in accordance with various embodiments; and

FIG. 3 is a flow diagram for a method of processing a semiconductor substrate in accordance with various embodiments.

### DETAILED DESCRIPTION

The following detailed description is merely illustrative in nature and is not intended to limit the embodiments of the subject matter or the application and uses of such embodiments. Furthermore, there is no intention to be bound by any expressed or implied theory presented in the preceding technical field, background, brief summary or the following detailed description.

Embodiments of the present disclosure provide methods of Chemical Mechanical Planarization (CMP) during semiconductor fabrication. The methods use non-rotational vibratory polishing between a semiconductor substrate and a polishing pad, as will be described below.

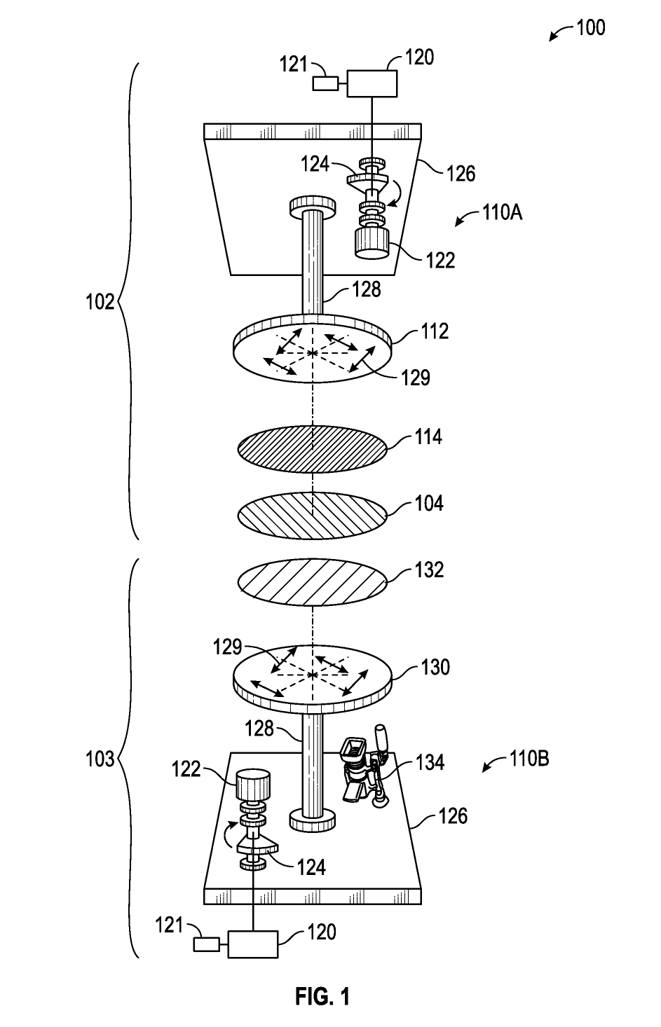

Referring now to FIG. 1, a CMP system 100 for fabricating semiconductor devices is illustrated in accordance with some embodiments. CMP system 100 includes a polish head assembly 102 and a platen assembly 103. Polish head assembly 102 holds a semiconductor substrate 104 during a CMP process. Semiconductor substrate 104 is a wafer on which integrated circuits are formed, as will be appreciated by those with skill in the art.

Polish head assembly 102 and platen assembly 103 create a relative oscillation or vibration between the semiconductor substrate 104 and a polish pad, as will be described below. Polish head assembly 102 includes a first vibration assembly 110A, a polishing head 112, and a head backing 114. In some embodiments, the first vibration assembly 110A is similar to the eccentric drive mechanism for liquid filtration described in U.S. Pat. No. 5,014,464, issued May 14, 1991, which is hereby incorporated by reference in its entirety.

In the example provided, first vibration assembly 110A includes a vibration actuator 120, a weighted rod 122, an eccentric weight 124, a seismic weight 126, and a torsion spring 128. Vibration actuator 120 may be, for example, an electrical motor driven by an alternating current power source. Vibration actuator 120 is coupled for electronic communication with a controller 121. Controller 121 commands a speed of an output shaft of vibration actuator 120 to adjust vibration characteristics of first vibration assembly 110A. Controller 121 is a computer system that may include any control circuitry capable of performing the various operations described below. For example, controller 121 may include a processor, such as a microprocessor, microcontroller, or digital signal processor (DSP), configured to execute instructions directing the processor to perform the operations enumerated below. In some embodiments, controller 121 may incorporate hardware-based logic, or may include a combination of hardware, firmware, and/or software elements.

Controller 121 includes a memory (not illustrated), which may be any device or component capable of storing digital data, such as one or more integrated circuits of static random access memory (SRAM), dynamic random access memory (DRAM), flash memory, and the like. In some implementations, the memory may be a magnetic or optical disk drive, or other type of storage device. In some embodiments, operations of the method described below may be stored as instructions in the memory or on other non-transitory computer readable media.

Weighted rod 122 is rotationally coupled with the output shaft of vibration actuator 120 and is supported by seismic weight 126. Eccentric weight 124 is coupled for rotation with weighted rod 122. The center of mass of eccentric weight 124 is offset from the center of weighted rod 122. Accordingly, when weighted rod 122 rotates, the forces of eccentric weight 124 are asymmetric about the axis of weighted rod 122, resulting in a transverse displacement of an end of weighted rod 122 within the plane of rotation of weighted rod 122.

Seismic weight 126 supports weighted rod 122 for rotation and is fixed to torsion spring 128. In the example provided, seismic weight 126 is a metal plate having a mass that is less than a mass of polishing head 112. During operation, seismic weight 126 is subject to the forces generated by the transverse displacement of weighted rod 122 caused by rotation of eccentric weight 124. These forces from weighted rod 122 cause seismic weight 126 to vibrate or move in an oscillatory manner. Seismic weight 126 is separated from the ground and other supporting surfaces by one or more isolation members (not shown). For example, seismic weight 126 may be supported by resilient members, such as elastomeric pads.

Torsion spring 128 is fixed to and extends from seismic weight 126. For example, torsion spring 128 may be welded to seismic weight 126 at the center of seismic weight 126. The characteristics of torsion spring 128 are selected so that the natural frequency of torsion spring 128 is such that torsion spring 128 resonates with the vibrations transmitted from the seismic weight 126. In the example illustrated, torsion spring 128 is a cylindrical metal rod. It should be appreciated that other shapes and materials may be utilized without departing from the scope of the present invention.

Torsion spring 128 is further secured to polishing head 112 to create vibrations, as indicated by arrows 129 of polishing head 112. It should be noted that torsional vibration of the polishing head 112 is 180 degrees out of phase from the complimentary motion of seismic weight 126. The phase difference results in a shear force on the head backing 114 and semiconductor substrate 104.

Platen assembly 103 includes a second vibration assembly 110B, a platen 130, a polishing pad 132, and a sensor 134. Second vibration assembly 110B is substantially similar to first vibration assembly 110A, where like numbers refer to like components. Second vibration assembly 110B, however, is coupled with platen 130 and polishing pad 132. Platen 130 is similar to polishing head 112 in size and shape. Polishing pad 132 has a diameter that is only slightly larger than a diameter of semiconductor substrate 104. Accordingly, a physical footprint of CMP system 100 is reduced from footprints of previous systems.

Polishing pad 132 is similar to conventional polishing pads, as will be appreciated by those with skill in the art. For example, polishing pad 132 may be a polymer-impregnated felt type pad, a porometrics type pad, a filled polymer sheet type pad, an unfilled textured polymer sheet type pad, or other types of pads that may be in use now or in the future.

Platen 130 includes a pressure grid that applies pressure to polishing pad 132 towards semiconductor substrate 104 at various portions of polishing pad 132. The pressure grid is particularly effective due to the lack of full rotation of polishing head 112 and platen 130, as opposed to traditional CMP systems where rotation of platens and polishing heads results in applied pressure in concentric rings.

Sensor 134 is further provided to detect the endpoint of a CMP process. For example, sensor 134 may be an optical camera or active flatbed scanner incorporated into platen 130, as will be appreciated by those with skill in the art. It should be appreciated that other types of sensors, such as acoustic sensors, velocity sensors, current sensors, and the like may be incorporated without departing from the scope of the present disclosure.

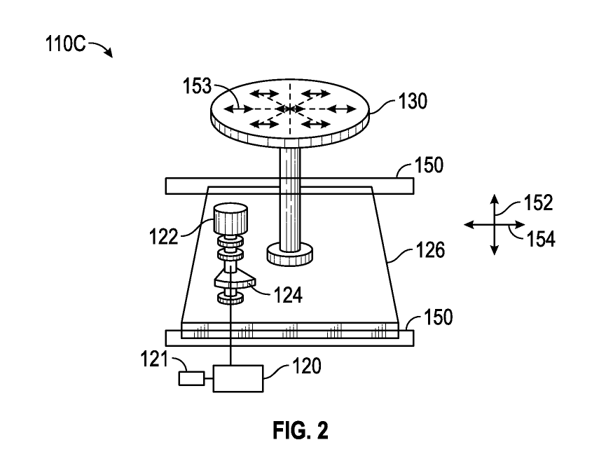

Referring now to FIG. 2, a vibration assembly 110C is illustrated according to some embodiments. Vibration assembly 110C is similar to first vibration assembly 110A and second vibration assembly 110B, where like numbers refer to like components. Vibration assembly 110C, however, includes tracks 150 in which the seismic weight 126 translates. The tracks 150 restrict vibration of the seismic weight 126 parallel to a first axis 152. The resulting vibrations, indicated by arrows 153, of the polishing head 112 are therefore perpendicular to the first axis 152 and parallel to a second axis 154. The axes 152 and 154 define a plane that is perpendicular to an axis of torsion spring 128 and parallel to a surface of platen 130.

In the example provided, vibration assembly 110C is incorporated into polish head assembly 102 instead of first vibration assembly 110A. It should be appreciated that vibration assembly 110C may also replace second vibration assembly 110B, or may be incorporated into other CMP assemblies without departing from the scope of the present disclosure. In some embodiments, one vibration assembly 110C is included in polish head assembly 102, and another vibration assembly 110C is included in platen assembly 103 at a 90 degree angle to first vibration assembly 110A. In such embodiments, vibrations 153 of polishing head 112 are perpendicular vibrations of platen 130.

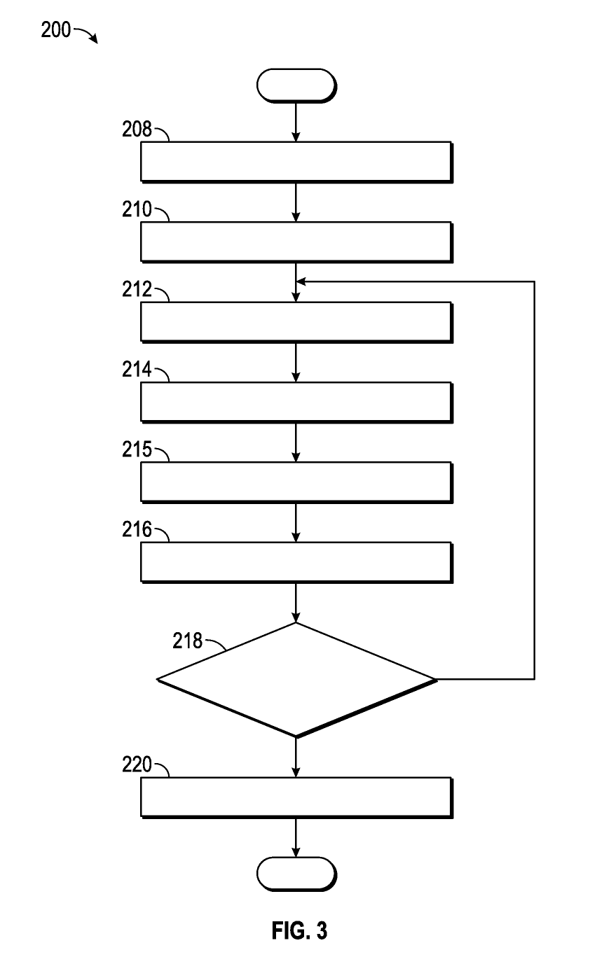

Referring now to FIG. 3, a flow diagram of a method 200 is illustrated according to some embodiments. In the example provided, operations of the method 200 are performed by CMP system 100. Method 200, however, may be performed by other systems that are capable of vibrating a polish pad and/or a semiconductor substrate in a controlled manner.

Operation 208 provides a semiconductor wafer on which a CMP process will be performed. For example, various automated substrate handling mechanisms may load the semiconductor substrate 104 into head backing 114 of polish head assembly 102.

Operation 210 selects a predetermined vibration profile based on desired and predetermined material removal characteristics, such as a rate of material removal and an amount of material to be removed from semiconductor substrate 104. In the example provided, controller 121 selects the predetermined vibration profile. The predetermined vibration profile indicates the vibrational intensity of vibrations 129 and/or vibrations 153 that will achieve the desired CMP removal characteristics. The desired CMP removal characteristics may include an amount of material to remove from the semiconductor substrate, a desired planarity, or other characteristics associated with CMP, as will be appreciated by those with skill in the art. In the example provided, the predetermined vibration profile is based on a peak to peak vibrational travel of about one centimeter to about one inch at polishing head 112 or platen 130 and about one to about 1,000 vibrations per second. For example, platen 130 may move one half centimeter to each side of a resting position along second axis 154 to result in a vibrational travel of about one centimeter at platen 130.

Operation 212 commands a first vibration actuator based on the predetermined vibration profile. For example, controller 121 may provide an electric current to vibration actuator 120 of first vibration assembly 110A. Operation 214 commands a second vibration actuator based on the predetermined vibration profile. For example, controller 121 of second vibration assembly 110B may provide an electric current to vibration actuator 120 of second vibration assembly 110B. In some embodiments, operations 212 and 214 command directional vibrations, such as vibrations 153 from vibration assembly 110C. Accordingly, the semiconductor substrate 104 and polishing pad 132 vibrate simultaneously in the example provided.

In some embodiments, operations 212 and 214 command directional vibrations that are perpendicular to each other. For example, two vibration assemblies 110C opposing each other and oriented to have respective vibrations 153 that are perpendicular to each other may be commanded by controllers 121. In some embodiments, operation 214 is omitted. When operation 214 is omitted, either semiconductor substrate 104 or polishing pad 132 may be selected to vibrate.

Operation 215 polishes the semiconductor substrate based on the predetermined vibrational profile. For example, CMP system 100 may bring semiconductor substrate 104 into physical contact with polishing pad 132. The physical contact may be achieved by translating polish head assembly 102, platen assembly 103, or other components of assemblies 102 and 103, as will be appreciated by those with skill in the art.

In the example provided, operation 215 is a non-rotational polish based substantially entirely on the predetermined vibration profile achieved by actuation of vibration actuators 120. Although some rotation may be induced by the vibration assemblies, polishing head 112 and/or platen 130 are not directly coupled with any rotational actuators. The term non-rotational means that the polishing head 112 and/or platen 130 are rotationally fixed, while also not precluding induced rotation through flexing or deformation of torsion spring 128.

For example, polishing head 112 is rotationally fixed to torsion spring 128, which is rotationally fixed to seismic weight 126, which is non-rotationally supported on a supporting surface. Accordingly, the rotation of polishing head 112 and/or platen 130 used in traditional CMP processes may be eliminated in favor of the vibrational motion disclosed herein. Therefore, pressure applied to specific areas of the back of semiconductor substrate 104 by head backing 114 transmit to polishing pad 132 in a grid fashion, rather than in the concentric circles that result from rotating head backing 114. For example, the pressure application may be based on a rotational position of a notch in the semiconductor substrate, which in the example provided does not change. This accurate pressure application results in improved uniformity throughout the CMP process.

Operation 216 monitors progress of the CMP material removal. For example, sensor 134 may be monitored to determine when to stop removing material. Operation 218 determines whether the desired CMP removal characteristics have been satisfied. When the desired CMP removal characteristics have not been satisfied, method 200 returns to operation 212 to continue material removal. When the desired CMP removal characteristics have been satisfied, method 200 proceeds to operation 220 where controllers 121 cease commanding vibration actuators 120 to halt material removal from semiconductor substrate 104.

The methods and systems disclosed herein exhibit several beneficial attributes. For example, methods and a system are disclosed that result in a substantially uniform velocity profile across the surface of a semiconductor substrate. Furthermore, pin-point accurate pressure distributions may be applied to the semiconductor substrate due to the non-rotating nature of the methods and system. These accurate pressure distributions permit a more accurate material removal from the semiconductor substrate. Furthermore, by vibrating the semiconductor substrate at high speeds, the methods described herein drive suspended foreign material in the polishing fluid and ultrapure rinse water away from the semiconductor substrate.

Those will skill in the art will further appreciate the methods and systems contemplated herein for other reasons. For example, shear forces at the wafer surface and at the polish pad are easily adjustable, a physical footprint of the system is reduced, removal rate may be increased, higher temperatures from friction may be achieved to initiate chemical reactions, higher throughput may be achieved due to increased removal rates, improved endpoint detection may be achieved due to an accentuated frictional transition between materials, recipes may be simplified due to elimination of complicated velocity gradients, less polishing fluid may be required, polish pad conditioning may be reduced or eliminated, and polish pad lifetime may be increased.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A method of processing a semiconductor substrate, the method comprising:
selecting a predetermined vibration profile that will achieve predetermined material removal characteristics from the semiconductor substrate in a chemical mechanical planarization (CMP) polish;
actuating a vibration actuator based on the predetermined vibration profile; and
polishing the semiconductor substrate based substantially entirely on the predetermined vibration profile achieved by actuation of the vibration actuator.

2. The method of claim 1, wherein polishing the semiconductor substrate further comprises maintaining a non-rotating platen.

3. The method of claim 1, wherein polishing the semiconductor substrate further comprises maintaining a non-rotating polishing head.

4. The method of claim 1, wherein actuating the vibration assembly further comprises actuating the vibration assembly to achieve a vibration frequency of about 1 to about 1000 vibrations per second between the semiconductor substrate and the polish pad.

5. The method of claim 1, wherein actuating the vibration assembly further comprises actuating the vibration assembly to achieve a displacement of a platen, a polishing head, or a combination thereof of about one centimeter to about 1 inch.

6. The method of claim 1, further comprising directionally vibrating a polishing head, a platen, or a combination thereof.

7. The method of claim 1, further comprising directionally vibrating a platen to create first directional vibrations.

8. The method of claim 7, further comprising directionally vibrating a polishing head to create second directional vibrations that are perpendicular to the first directional vibrations.

9. The method of claim 1, wherein actuating a vibration actuator includes rotating an eccentric weight.

10. The method of claim 9, wherein rotating the eccentric weight includes vibrating a seismic weight that is fixed to a torsion spring on which a platen or a polishing head is secured.

11. A method of fabricating a semiconductor device, the method comprising:
selecting a predetermined vibration profile that will achieve predetermined material removal characteristics from the semiconductor substrate in a chemical mechanical planarization (CMP) polish;
actuating a vibration actuator based on the predetermined vibration profile; and
polishing the semiconductor substrate based substantially entirely on the predetermined vibration profile achieved by actuation of the vibration actuator and on maintaining a non-rotating platen and a non-rotating polishing head.

12. The method of claim 11, wherein actuating the vibration assembly further comprises actuating the vibration assembly to achieve a vibration frequency of about 1 to about 1000 vibrations per second between the semiconductor substrate and the polish pad.

13. The method of claim 11, wherein actuating the vibration assembly further comprises actuating the vibration assembly to achieve a displacement of the platen, the polishing head, or a combination thereof of about one centimeter to about 1 inch.

14. The method of claim 11, further comprising directionally vibrating the polishing head, the platen, or a combination thereof.

15. The method of claim 11, further comprising directionally vibrating the platen to create first directional vibrations.

16. The method of claim 11, further comprising directionally vibrating a polishing head to create second directional vibrations that are perpendicular to the first directional vibrations.

17. The method of claim 11, wherein actuating a vibration actuator includes rotating an eccentric weight.

18. The method of claim 17, wherein rotating the eccentric weight includes vibrating a seismic weight that is fixed to a torsion spring on which a platen or a polishing head is secured.

19. A chemical mechanical planarization (CMP) system comprising:
a platen;
a polishing head opposing the platen; and
a vibration assembly coupled with the platen, the polishing head, or a combination thereof, the vibration assembly including a controller capable of:
selecting a predetermined vibration profile that will achieve predetermined material removal characteristics from the semiconductor substrate in a chemical mechanical planarization (CMP) polish;
actuating a vibration actuator based on the predetermined vibration profile; and
polishing the semiconductor substrate based substantially entirely on the predetermined vibration profile achieved by actuation of the vibration actuator and on maintaining a non-rotating platen and a non-rotating polishing head.
